(19) United States
(12) Patent Application Publication
(10) Pub. No.: US 2018/0269266 A1
(43) Pub. Date: Sep. 20, 2018

(54) FOVEATED DISPLAYS FOR VIRTUAL AND AUGMENTED REALITY

(71) Applicant: Intel Corporation, Santa Clara, CA (US)

(72) Inventors: Ramon C. Cancel Olmo, Hillsboro, OR (US); Khaled Ahmed, Anaheim, CA (US)

(21) Appl. No.: 15/461,215

(22) Filed: Mar. 16, 2017

(51) Int. Cl. H01L 27/32; H01L 27/28

(52) U.S. Cl. CPC H01L 27/3218; H01L 2227/323; H01L 27/3267; H01L 27/286

(57) ABSTRACT

Embodiments related to foveated display devices having first display elements having a first display element density in a first region of a display and second display elements having a second display element density less than the first display element density in a second region of the display are discussed.

### BACKGROUND

Virtual reality (VR) and augmented reality (AR) display devices and applications require high pixel densities to produce a pristine quality viewing experience for users. For example, a display may require several thousand pixels per inch (PPI) depending on the display size and the optics of the device. Such pixel densities put a tremendous toll on the graphics engine rendering images for the display, require large power consumption, and can be costly to fabricate and operate.

As such, there is a continual demand for improved VR and AR displays, devices, systems, and fabrication techniques. It is with respect to these and other considerations that the present improvements have been needed. Such improvements may become critical as the desire to provide high quality VR and AR displays in a variety of devices such as wearable devices becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A is a plan view of an example foveated display including regions of differing display element densities;

FIG. 1B is a cross-sectional view of an example display element layout of the foveated display of FIG. 1A;

FIG. 1C is a second cross-sectional view of the example display element layout of the foveated display of FIG. 1A;

FIG. 1D is a cross-sectional view of a second example display element layout of the foveated display of FIG. 1A;

FIG. 1E is a second cross-sectional view of the second example display element layout of the foveated display of FIG. 1A;

FIG. 2 is a plan view of an example foveated display including regions of differing display element densities with a serrated edge between the regions;

FIG. 3 is a plan view of an example foveated display including regions of differing display element densities with a region having an elliptical shape;

FIG. 4A is a plan view of another example foveated display including regions of differing display element densities;

FIG. 4B is a cross-sectional view of the example foveated display of FIG. 4A;

FIG. 4C is a second cross-sectional view of the example foveated display of FIG. 4A;

FIG. 4D is a third cross-sectional view of the example foveated display of FIG. 4A;

FIG. 4E is a fourth cross-sectional view of the example foveated display of FIG. 4A;

FIG. 5 is a plan view of an example foveated display including a gradient of differing display element densities;

FIG. 6 is a plan view of example left and right foveated displays including regions of differing display element densities for dual display applications;

FIG. 7 is an illustrative diagram of an example virtual reality system including dual foveated displays;

FIG. 8A is an illustrative diagram of an example augmented reality system including a foveated display;

FIG. 8B is an illustrative diagram of another example augmented reality system including a foveated display;

FIG. 9 is a flow diagram illustrating an example process for fabricating a foveated display device;

FIG. 10 illustrates example pick and place operations for the fabrication of a foveated display device;

FIG. 11 illustrates a system in which a mobile computing platform employs a foveated display; and

FIG. 12 is a functional block diagram of a computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth, however, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “in one embodiment” means that a particular feature, structure, function, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the two embodiments are not specified to be mutually exclusive.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” my be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

Display devices, apparatuses, virtual reality systems, augmented reality systems, computing platforms, and fabrication techniques are described below related foveated displays.

Human visual acuity is greater near the middle of the field of view and radiates to lower capabilities in the peripheral vision. For example, the macular region of the human field of view (e.g., about 18° of the field of view around the centerline) is the region with the highest ability to observe detail. A central region extending from the macular region to about 30° of the field of view around the centerline may be characterized as a near peripheral region and the remaining field of view may be characterized as a peripheral region (the peripheral region may optionally be divided into mid and far peripheral regions). The central region visual filed, in the human visual system, is dominated by cones (i.e., in the fovea), which rapidly decrease in density moving to the peripheral region, where rods provide the majority of the visual acuity and visual acuity is, therefore, greater in the middle of the field of view and lesser radiating outwardly from the middle.

The techniques and devices discussed herein provide a foveated display that features a nonhomogeneous pixel arrangement that matches, nearly matches, or takes advantage of the foveal map of the human eye (e.g., higher resolution within a smaller centralized field of view and radiating outward with a decreasing resolution). Such foveated displays having physical display elements that are at different display element densities or pixel densities may provide a variety of advantages. In some contexts, such as pick and place fabrication for light emitting diodes, the foveated display reduces the number of transfers (and thereby cost) needed to fabricate the display. Furthermore, in operation, the foveated display may reduce the total number of pixels that need to be activated to save power and compute cycles. Such advantages may be provided while minimally impacting the user experience of a user of the display device due to the discussed characteristics of human vision.

In some embodiments discussed herein, a foveated display device includes a plurality of first display elements on a first region of a display substrate and a plurality of second display elements on a second region of the display substrate. The first display elements are at a first display element density and the second display elements are at a second display element density different than the first display element density. As is discussed further herein, the display element density in a region at a center of a field of view may be higher than the display element density in a region that is further from the center of the field of view. Furthermore, in some applications, a second display device having display elements at different display element densities may also be provided. For example, a virtual reality (VR) device may include left and right optics and left and right foveated displays to provide stereoscopic VR imagery to a user. In such contexts, the left foveated display may have higher display element density in a region centered between the center of the left foveated display and the right edge of the left foveated display and the right foveated display may have higher display element density in a region centered between the center of the right foveated display and the left edge of the right foveated display. Such an arrangement of higher display element density regions may take advantage of the higher acuity of users toward the center of their field of view while providing advantages of lesser display element density regions (e.g., reduced manufacturing costs and reduced operating costs) where the acuity of user is lower (e.g., in peripheral or temporal regions of view).

As used herein, the term display element may be any element or elements that provide a physical display capability for the display device. For example, the display elements may be characterized as pixels or the like. In some embodiments, each display element has a capability of emitting or manipulating a red component, a green component, and a blue component. For example, the display elements may be light emitting diode (LED) or micro-LED display elements or emitters, organic light emitting diode (OLED) display elements, liquid crystal display (LCD) display elements, or the like. In an embodiment, the display elements are inorganic LEDs or micro-LEDs disposed on a monolithic display substrate to provide a monolithic foveated RGB LED or micro-LED display. Such display elements may be self-emitting (e.g., they may emit light directly) or they may manipulate or modulate light emitted by another device (e.g., a back light or the like). The sub-display elements (e.g., the red, green and blue emitters or modulators) may have the same spacing within the regions or the spacing between the sub-display elements may increase as the display element density increases. One or more such foveated displays may be employed in a system that may include a processor, optical components, and other components such as a wireless transceiver or the like. Such a system may be provided in any suitable form factor device such as virtual reality device such as a headset, an augmented reality device, a watch, a mobile device such as a smartphone, a tablet, a laptop, a phablet (e.g., a 5 inch side display), or the like or as a discrete display device or the like.

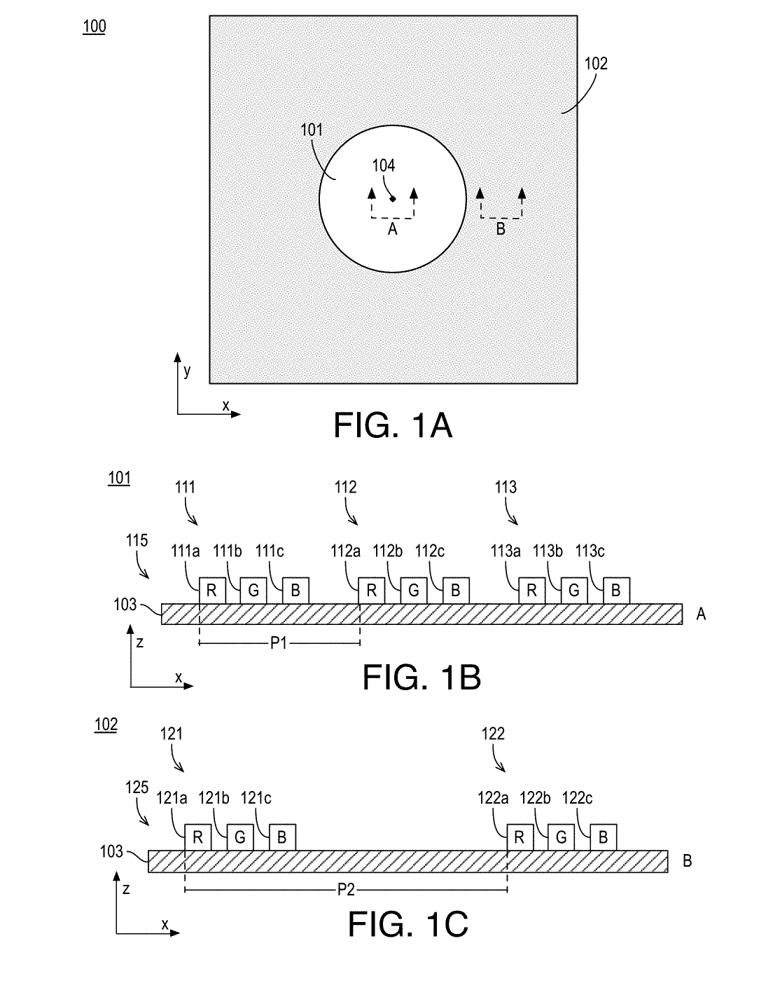

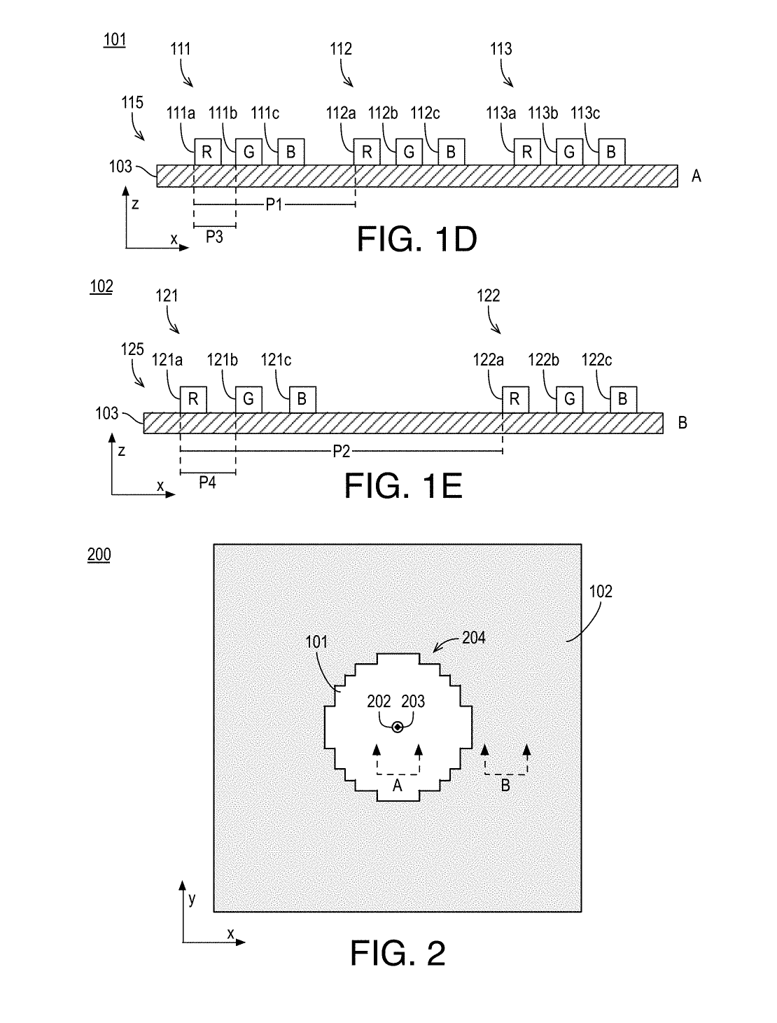

FIG. 1A is a plan view of an example foveated display 100 including regions of differing display element densities, arranged in accordance with at least some implementations of the present disclosure. FIG. 1B is a cross-sectional view of an example display element layout of foveated display 100 taken along plane A as shown in the plan view of FIG. 1A. FIG. 1C is a second cross-sectional view of the example display element layout of foveated display 100 taken along plane B as shown in the plan view of FIG. 1A. FIG. 1D is a cross-sectional view of a second example display element layout of foveated display 100 taken along plane A as shown in the plan view of FIG. 1A. FIG. 1E is a second cross-sectional view of the second example display element layout of foveated display 100 taken along plane B as shown in the plan view of FIG. 1A.

Foveated display 100 and other foveated displays discussed herein may be characterized as a foveated display device, a foveated display system, a display, or the like. In an embodiment, the display elements are inorganic LEDs or micro-LEDs disposed on a monolithic display substrate to provide a monolithic foveated RGB LED or micro-LED display. Furthermore, foveated display 100 and other foveated displays discussed herein may include or be connected to other elements or components such as a back plane or back plate, electrodes or other circuitry such as control or power circuitry, a translucent front plate such as a glass front plate, or the like. Foveated display 100 and other foveated displays discussed herein may be implemented in any suitable form factor device such as a virtual reality headset, and augmented reality headset, a watch, a headset, a mobile device such as a smartphone, a tablet, a laptop, a phablet, or the like or as a discrete display device or the like. Foveated display 100 may be square, as shown, or foveated display 100 may be rectangular (e.g., with a longer axis in the horizontal or x-direction and a shorter axis in the vertical or y-direction) or any other suitable shape.

As shown, foveated display 100 includes a region 101 having display elements 111, 112, 113 at a display element density 115 and a region 102 having display elements 121, 122 at a display element density 125 on a display substrate 103. Although illustrated with two regions having display elements of different display element densities, foveated display 100 may have any number of regions of different display element densities as is discussed further herein. Furthermore, although illustrated with continuous discrete regions having display elements of different display element densities, foveated display 100 may have a gradient pattern such that display element densities decrease along a gradient as is discussed further herein.

Display substrate 103 may be any suitable substrate, carrier, backplane, or the like and display substrate 103 may include or be coupled to circuitry for driving foveated display 103. In an embodiment, display substrate 103 is a thin film transistor (TFT) backplane. In an embodiment, display substrate 103 is a glass substrate having thin film transistors (TFT) formed thereon. As shown in FIGS. 1B and 1C, display elements 111, 112, 113 may be spaced apart from one another at a pitch P1 and display elements 121, 122 may be spaced apart from one another at a pitch P2 such that P2 is greater than P1 to provide display element density 125 having a lesser density than display element density 115. For examples, pitches P1 and P2 may be provided in both the x-dimension and the y-dimension or different pitches may be provided in the x- and y-dimensions to provide the discussed display element densities. Display element densities 115, 125 may be any suitable densities such that display element density 125 is less than display element density 115. In an embodiment, display element density 115 is in the range of about 2,800 to 3,200 pixels per inch (PPI) such as about 3,000 PPI and display element density 125 is in the range of about 1,500 to 2,000 PPI such as about 1,800 PPI. In an embodiment, a ratio of display element density 125 to display element density 115 may be about 75%. In an embodiment, display element density 125 is not more than three-quarters display element density 115. In an embodiment, display element density 115 is in the range of about 800 to 1,200 pixels per inch (PPI) such as about 1,000 PPI and display element density 125 is in the range of about 400 to 600 PPI such as about 500 PPI. As used herein, PPI may be interchanged with display element per inch.

As shown in FIGS. 1A-1C, in some embodiments, each of display elements 111, 112, 113 and display elements 121, 122 include a red emitter 111a, 112a, 113a, 121a, 122a, a green emitter 111b, 112b, 113b, 121b, 122b, and a blue emitter 111c, 112c, 113c, 121c, 122c. In an embodiment, each of display elements 111, 112, 113 and display elements 121, 122 includes a respective red light emitting diode (LED), green LED, and blue LED. In another embodiment, each of display elements 111, 112, 113 and display elements 121, 122 includes a respective red micro-LED, green micro-LED, and blue micro-LED. In an embodiment, each of display elements 111, 112, 113 and display elements 121, 122 includes a respective red organic LED, green organic LED, and blue organic LED. In such examples, display elements 111, 112, 113 and display elements 121, 122 may be characterized as self-emitting or the like. In other examples, display elements 111, 112, 113 and display elements 121, 122 are light modulating devices such as liquid crystal display (LCD) devices that manipulate light from a back light or a back plane (not shown).

In any event, display elements 111, 112, 113 and display elements 121, 122 are physical display devices or structures that are individually addressable to provide light (e.g., either a single color or multiple color channels) for a portion of foveated display 100. For example, display elements 111, 112, 113 and display elements 121, 122 provide the smallest addressable or manipulative element for region 101 and region 102, respectively. In the illustrated embodiment, display elements 111, 112, 113 and display elements 121, 122 are the same display elements such that each of display elements 111, 112, 113 and display elements 121, 122 includes red, green, and blue display elements (either emissive or passive as discussed). In other embodiments, display elements 111, 112, 113 and display elements 121, 122 may be different display elements. For example, display elements 111, 112, 113 may be any or a combination of LED display elements, micro-LED display elements, organic LED (OLED) display elements, or LCD display elements while display elements 121, 122 are different display elements and also any or a combination of LED display elements, micro-LED display elements, organic LED (OLED) display elements, or LCD display elements.

Furthermore, in embodiment illustrated in FIGS. 1B and 1C, display elements 111, 112, 113 and display elements 121, 122 are the same type and size and have the same orientation and layout. In other embodiments, display elements 111, 112, 113 and display elements 121, 122 may be different sizes (e.g., display elements 121, 122 may be slightly larger as allowed by the spacing of pitch P2) or they may be oriented differently or have a different layout. Furthermore, in the illustrated embodiment, each of display elements 111, 112, 113 and display elements 121, 122 have three display elements for three color channels (i.e., red, green and blue) at the same density. In other embodiments, some or all of display elements 111, 112, 113 and display elements 121, 122 may have a display element for a single color channel (e.g., white or a particular color) or display elements for two color channels. For example, foveated display 100 may be single color display or foveated display 100 may provide a full color display but with less than all three color channels at each pixel location.

As shown in FIGS. 1D and 1E, in some embodiments, display elements 111, 112, 113 may be spaced apart from one another at a pitch P1 and display elements 121, 122 may be spaced apart from one another at a pitch P2 such that P2 is greater than P1 to provide display element density 125 having a lesser density than display element density 115 as discussed with respect to FIGS. 1B and 1C. Furthermore, the sub-display elements or sub-pixels of region 101 may be more densely packed than the sub-display elements or sub-pixels of region 102. For example, red emitter 111a may be spaced at a pitch of P3 from green emitter 111b and green emitter 111b may be spaced at a pitch of P3 from blue emitter 111c. Emitters 112a, 112b, and 112c as well as emitters 113a, 113b, and 113c (and other emitters of display elements in region 101) may be provided at the same or similar pitch such that each of display elements 111, 112, 113 are provided at a corresponding sub-element density. Also as shown, red emitter 121a may be spaced at a pitch of P4 from green emitter 121b and green emitter 121b may be spaced at a pitch of P4 from blue emitter 121c. Emitters 122a, 122b, and 122c and other emitters of display elements in region 102 may be provided at the same or similar pitch such that each of display elements 121, 122 are provided at a corresponding sub-element density less than the sub-element density of display elements 111, 112, 113 of region 101. For example, the decreased display element density in region 102 with respect to region 101 may coincide with a decreased sub-element (e.g., sub-pixel, emitter, modulator, etc.) density in region 102 with respect to region 101. Such increased distances between sub-display elements may be particularly advantageous in LED and OLED implementations. In addition or in the alternative, the sizes of the sub-display elements in region 102 may increase with respect to the sub-display elements in region 101. The display element densities (e.g., as provided by pitches P1 and P2 may be any display element densities discussed with respect to FIGS. 1B and 1C and elsewhere herein.

As shown in FIG. 1A, in some embodiments, region 101 is substantially circular and region 101 is centered or substantially centered with a center point 104 of foveated display 100 (e.g., such that a center point of region 101, not shown, is at the same location as center point 104). Furthermore, regions 101, 102 are both single continuous regions with region 102 fully surrounding region 101. Also, in the illustrated embodiment, each display element of region 102 is farther from center point 104 than each display element of region 101. Such a layout may provide, in the context of a single foveated display 100, an example of greater display element density within the most sensitive region of a user's field of view and lower display element density within a region that is less sensitive.

However, region 101 may have any suitable shape such as an elliptical or oval shape (e.g., with a longer axis in the horizontal or x-direction and a shorter axis in the vertical or y-direction), a square shape, a rectangular shape (e.g., with a longer axis in the horizontal or x-direction and a shorter axis in the vertical or y-direction), a cross shape, a diamond shape, or the like. Furthermore, multiple regions 101 of greater display element density may be provided. In some embodiments, the center of region 101 may be misaligned with center point 104 of foveated display 100. Additionally, region 101 and region 102 may be homogenous in that they each have the same display element densities throughout. In another embodiment, foveated display 100 may have a gradient reduction in display element densities from a central region of region 101 to an edge of region 102 (e.g., an edge of the foveated display).

FIG. 2 is a plan view of an example foveated display 200 including regions of differing display element densities with a serrated edge between the regions, arranged in accordance with at least some implementations of the present disclosure. As shown in FIG. 2, foveated display 200 includes region 101 and region 102, which include display elements 111, 112, 113 at a display element density 115 and a region 102 having display elements 121, 122 at a display element density 125 on a display substrate 103, as discussed with respect to FIGS. 1B-1E. For example, views along planes A and B in FIG. 2 are also provided by FIGS. 1B and 1C or FIGS. 1D and 1E. Regions 101, 102 of foveated display 200 and the display elements thereof may have any characteristics as discussed herein such as those discussed with respect to FIGS. 1A-1E. Foveated display 200 may be square, as shown, or foveated display 100 may be rectangular (e.g., with a longer axis in the horizontal or x-direction and a shorter axis in the vertical or y-direction) or any other suitable shape. As shown, in an embodiment, center point 202 (illustrated with a black diamond) of region 101 may be aligned with center point 203 (illustrated with an open circle) of foveated display 200.

Also as shown in FIG. 2, region 101 may have a serrated edge 204 such that display elements of region 101 and region 102 at serrated edge 204 are aligned in a horizontal or x-direction or a vertical or y-direction along serrated edge 204. For example, FIG. 1A illustrates an embodiment of region 101 of foveated display 100 such that region 101 has a substantially smooth edge. Of course, the smooth edge of region 101 may be smooth only at the pixel density available. In the embodiment of region 101 of foveated display 200, serrated edge 204 may be provided at any suitable granularity or pixel width and height or the like. For example, each horizontal or vertical edge of serrated edge 204 may be limited to not more than a particular number of display elements of region 101 such as 20 display elements (e.g., pixels), 10 display elements, or the like.

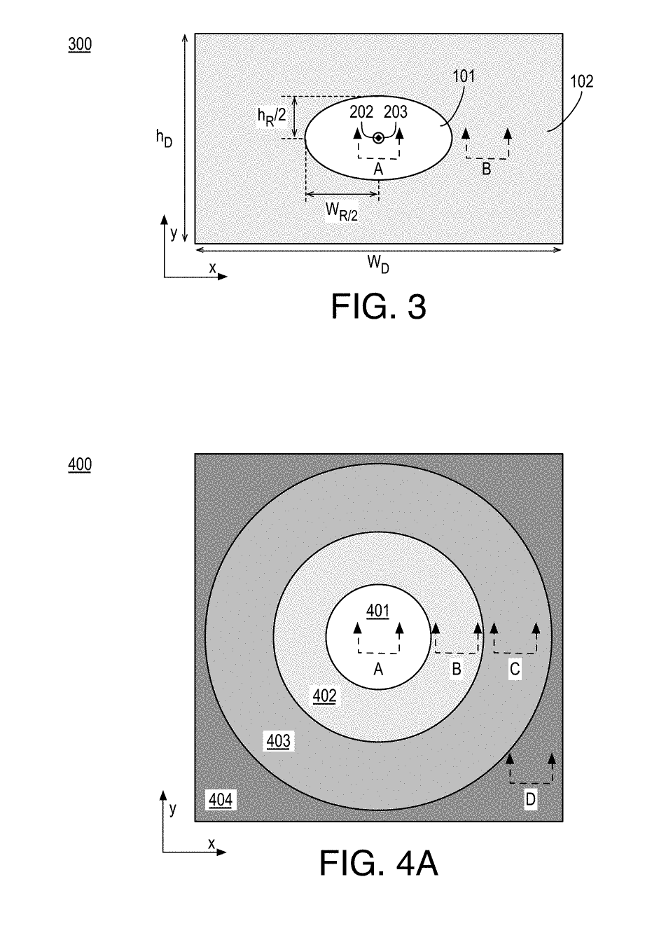

FIG. 3 is a plan view of an example foveated display 300 including regions of differing display element densities with a region having an elliptical shape, arranged in accordance with at least some implementations of the present disclosure. As shown in FIG. 3, foveated display 300 includes region 101 and region 102, which include display elements 111, 112, 113 at a display element density 115 and a region 102 having display elements 121, 122 at a display element density 125 on a display substrate 103, as discussed with respect to FIGS. 1B-1E. For example, views along planes A and B in FIG. 3 are also provided by FIGS. 1B and 1C or FIGS. 1D and 1E. Regions 101, 102 of foveated display 300 and the display elements thereof may have any characteristics as discussed herein such as those discussed with respect to FIG. 1A-1E.

In particular, FIG. 3 illustrates an example foveated display 300 having region 101 with an elliptical shape and foveated display 300 having a rectangular shape. Region 101 of display 300 may have a smooth edge as shown in FIG. 3 or a serrated edge as discussed with respect to FIG. 2. As shown, foveated display 300 has a width, W_{D}, and a height, h_{D}, such that W_{D} is greater than h_{D} providing an aspect ratio of W_{D}:h_{D}. Foveated display 300 may have any suitable aspect ratio such as an aspect ratio of about 16:9. Furthermore, the elliptical shape of region 101 has a major axis length (e.g., a horizontal or x-direction length), W_{R}, and a minor axis length (e.g., a vertical or y-direction length), h_{R}, such that W_{R} is greater than h_{R} and a major axis to minor axis ratio of W_{R}:h_{R}. In an embodiment, the major to minor axis ratio of the elliptical shape of region 101 may match or nearly match the aspect ratio of foveated display 300. Such a configuration may provide for region 101 having increased lateral or horizontal coverage with respect to its vertical coverage for improved user experience. As discussed, the major to minor axis ratio of the elliptical shape of region 101 may match or nearly match the aspect ratio of foveated display 300. For example, the major to minor axis ratio of the elliptical shape of region 101 may be within a particular percentage of the aspect ratio of foveated display 300 such as one percent, two percent, five percent, or the like. As shown, in an embodiment, center point 202 (illustrated with a black diamond) of region 101 may be aligned with center point 203 (illustrated with an open circle) of foveated display 300.

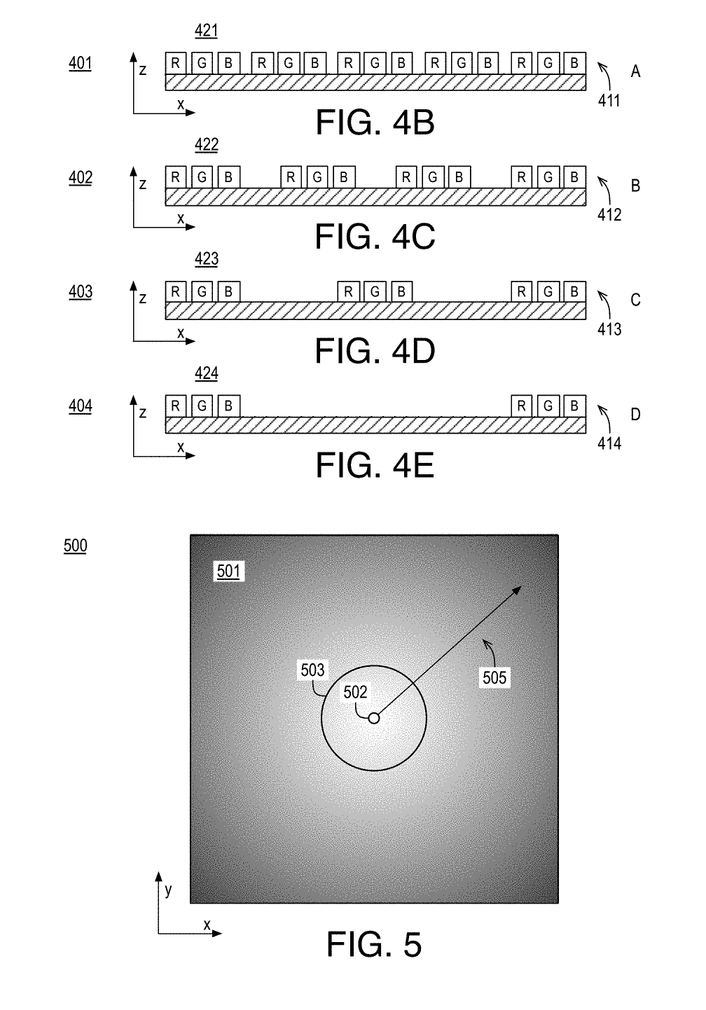

FIG. 4A is a plan view of an example foveated display 400 including regions of differing display element densities, arranged in accordance with at least some implementations of the present disclosure. FIG. 4B is a cross-sectional view of foveated display 400 taken along plane A as shown in the plan view of FIG. 4A. FIG. 4C is a cross-sectional view of foveated display 400 taken along plane B as shown in the plan view of FIG. 4A. FIG. 4D is a cross-sectional view of foveated display 400 taken along plane C as shown in the plan view of FIG. 4A. FIG. 4E is a cross-sectional view of foveated display 400 taken along plane D as shown in the plan view of FIG. 4A.

As shown, in an embodiment, foveated display 400 may have more than two regions having differing display element densities. Although illustrated with four regions having display elements of different display element densities, foveated display 400 may have any number of regions of different display element densities such as three, five, or more. As shown in FIGS. 4B-4E, display elements 411 of region 401 may be spaced apart from one another such that a display element density 421 is provided in region 401, display elements 412 of region 402 may be spaced apart from one another such that a display element density 422 is provided in region 402, display elements 413 of region 403 may be spaced apart from one another such that a display element density 423 is provided in region 403, and display elements 414 of region 404 may be spaced apart from one another such that a display element density 424 is provided in region 404. Also as shown, display element density 421 is greater than display element density 422, which is greater than display element density 423, which is greater than display element density 424.

As shown, in some embodiments, each display element of display elements 411, 412, 413, 414 include a red, green, and a blue emitter. However, the display elements may include any suitable display elements discussed herein such as LEDs, micro-LEDs, organic LEDs, LCD elements having one, two, or three colors. Furthermore, as discussed herein, each display element is a physical display device or structure that is individually addressable to provide light (e.g., either a single color or multiple color channels) for a portion of foveated display 400. For example, each display element of display elements 411, 412, 413, 414 provide the smallest addressable or manipulative element for regions 401, 402, 403, 404, respectively. Display elements 411, 412, 413, 414 may all be of the same type and size or any of display elements may be of different types or sizes.

In the example of FIG. 4A, regions 401, 402, 403 are substantially circular or annular and centered or substantially centered with the center of foveated display 400. Furthermore, regions 401, 402, 403, 404 are each single continuous regions with region 402 fully surrounding region 401, region 403 fully surrounding region 402, and region 404 fully surrounding region 403. Also, in the illustrated embodiment, each display element of region 402 is farther from the center of foveated display 400 than each display element of region 401, each display element of region 403 is farther from the center of foveated display 400 than each display element of region 402, and each display element of region 404 is farther from the center of foveated display 400 than each display element of region 403. However, regions 401, 402, 403 may have any suitable shapes in any suitable combination. For example, one or more of regions 401, 402, 403 may have an elliptical or oval shape (e.g., with a longer axis in the horizontal or x-direction and a shorter axis in the vertical or y-direction), a square shape, a rectangular shape (e.g., with a longer axis in the horizontal or x-direction and a shorter axis in the vertical or y-direction), a cross shape, a diamond shape, an elliptical annular shape, a square annulus shape, a rectangular annulus shape, or the like. In some embodiments, one or more of regions 401, 402, 403 have serrated edges as discussed with respect to FIG. 2. In some embodiments, the center of one or more of regions 401, 402, 403 may be misaligned with the center point of foveated display 400.

Display element densities 421, 422, 423, 424 may be any suitable display element densities such that display element density 421 is greater than display element density 422, display element density 422 is greater than display element density 423, and display element density 423 is greater than display element density 424. In an embodiment, display element density 421 is in the range of about 2,800 to 3,200 pixels per inch (PPI) such as about 3,000 PPI, display element density 422 is in the range of about 2,000 to 2,500 PPI such as about 2,250 PPI, display element density 423 is in the range of about 1,250 to 1,750 PPI such as about 1,500 PPI, and display element density 424 is in the range of about 500 to 1,000 PPI such as about 750 PPI.

In some embodiments, a ratio of display element density 422 to display element density 421 may be about 75%, a ratio of display element density 423 to display element density 421 may be about 50%, and/or a ratio of display element density 424 to display element density 421 may be about 25%. In an embodiment, display element density 422 is not more than three-quarters display element density 421, display element density 423 is not more than one-half display element density 421, and/or display element density 424 is not more than one-quarter display element density 421.

In an embodiment, foveated display 400 includes three regions (e.g., regions 401, 402 as illustrated and region 403 extending to the edges of foveated display 400). In such embodiments, display element density 421 may be in the range of about 2,800 to 3,200 pixels per inch (PPI) such as about 3,000 PPI, display element density 422 may be in the range of about 1,500 to 2,100 PPI such as about 1,800 PPI, and display element density 423 may be in the range of about 400 to 800 PPI such as about 600 PPI.

In an embodiment, foveated display 400 includes five regions of differing display element densities radiating from the center point of foveated display 400 with a first ratio of a display element density to a maximum display element density of about 75%, a second ratio of a display element density to the maximum display element density of about 50%, a third ratio of a display element density to the maximum display element density of about 25%, and a fourth ratio of a display element density to the maximum display element density of about 12.5%.

Furthermore, the display elements of regions 401, 402, 403, 404 may have the same sub-display element density or the sub-display element densities may decrease with decreasing display element densities (as discussed with respect to FIGS. 1D and 1E) such that region 401 has a greater sub-display element density than region 402, region 402 has a greater sub-display element density than region 403, and region 403 has a greater sub-display element density than region 402.

FIG. 5 is a plan view of an example foveated display 500 including a gradient of differing display element densities, arranged in accordance with at least some implementations of the present disclosure. As shown in FIG. 5, foveated display 500 includes a region 501 having a gradient of display element densities decreasing from a center point 502 of foveated display along a decreasing gradient direction 505. For example, along circles or annular regions (or any other shape discussed herein) centered with respect to center point 502 such as circle 503 of foveated display 500 may have approximately the same or equivalent display element densities with the display density decreasing along larger with larger concentric circles, concentric ellipses, concentric squares, concentric rectangles, annular regions, or rings moving along decreasing gradient direction 505. In some embodiments, the decrease in display element density along decreasing gradient direction 505 may be linear. In other embodiments, the decrease in display element density along decreasing gradient direction 505 may be non-linear (e.g., with a lower decrease closely around center point 502 and a higher decrease extending away from center point 502). The gradient of differing display element densities may be provided using a gradual change in display element densities, a stepped change in display element densities, or the like.

Furthermore, the display elements of foveated display 500 may have the same sub-display element density along gradient direction 505 and across region 501 or the sub-display element densities may decrease with decreasing display element densities (as discussed with respect to FIGS. 1D and 1E) such that along gradient direction 505 the sub-display element density decreases along with the decreasing display element density.

As discussed, foveated displays 100, 200, 300, 400, 500 (e.g., a single foveated display) may be implemented in some contexts such as single display virtual reality devices. In other implementations, two foveated displays (e.g., dual foveated displays) may be provided.

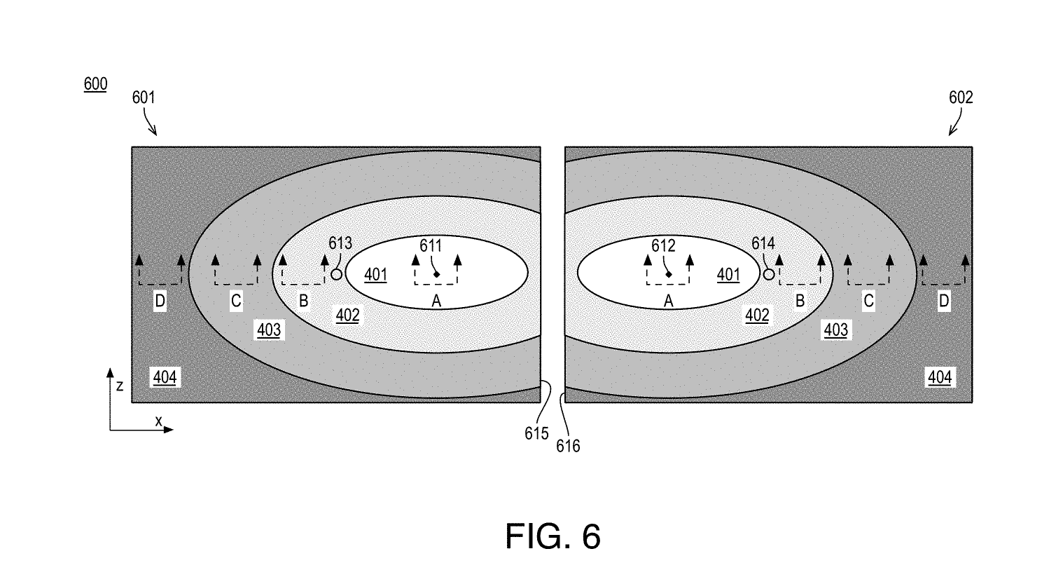

FIG. 6 is a plan view of example left and right foveated displays 601, 602 including regions of differing display element densities for dual display applications, arranged in accordance with at least some implementations of the present disclosure. As shown in FIG. 6, left foveated display 601 and right foveated display may each include regions 401, 402, 403, 404 including display elements 411, 412, 413, 414 at display element densities 421, 422, 423, 424 as discussed with respect to FIGS. 4B-4E. For example, views along planes A, B, C and D in FIG. 6 are also provided by FIGS. 4B-4E. Regions 401, 402, 403, 404 of foveated displays 601, 602 may have any characteristics as discussed herein such as those discussed with respect to FIGS. 1A-1E, those discussed with respect to FIGS. 4A-4E, or those discussed with respect to FIG. 5. Foveated displays 601, 602 may be rectangular, as shown, with a longer axis in the horizontal or x-direction and a shorter axis in the vertical or y-direction, or foveated displays 601, 602 may be square or any other suitable shape.

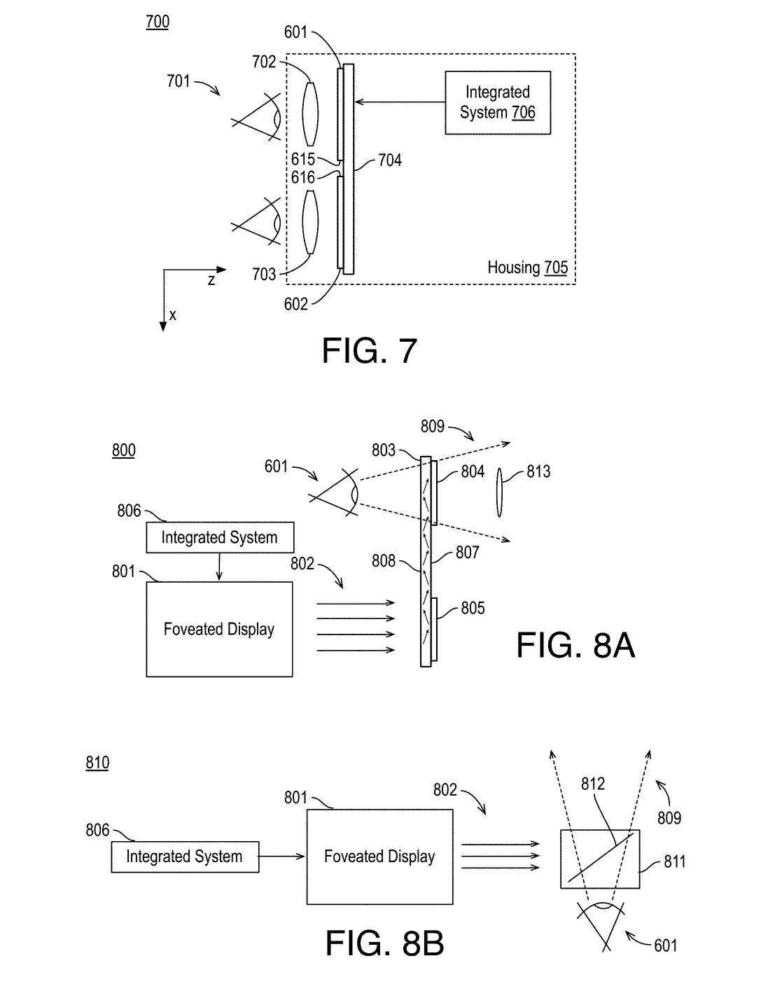

Also as shown, foveated displays 601, 602 may be implemented adjacent to one another such that a right edge 615 of left foveated display 601 is adjacent to (e.g., either in contact with or with a slight gap between) a left edge 616 of right foveated display 616. As is illustrated below with respect to FIG. 7, such a configuration may provide for a user to view foveated displays 601, 602 simultaneously through left and right optics, respectively, such that a stereoscopic virtual image is provided for the user.

As discussed, in an embodiment, foveated displays 601, 602 may each include regions 401-404 having any characteristics discussed with respect to FIGS. 4A-4E. As shown, in some examples, foveated displays 601, 602 are mirror images of one another and otherwise have the same characteristics. For example, regions 401-404 of foveated display 601 may have the same display element densities as regions of foveated display 602. For example, regions 401-404 of foveated display 601 may have the same display element densities as regions of foveated display 602 within a particular error such as less than 0.1 percent, less than one percent, or the like. In other examples, foveated displays 601, 602 may have different shapes or alignments of regions 401-404, different shapes or numbers or regions, or different display element densities therein.

Furthermore, as shown, a center point 611 of regions 401-403 of foveated display 601 may be misaligned with respect to a center point 613 of foveated display 601 such that center point 611 is between center point 613 and edge 615. Similarly, a center point 612 of regions 401-403 of foveated display 602 may be misaligned with respect to a center point 614 of foveated display 601 such that center point 612 is between center point 614 and edge 616. Such an alignment may offer the advantage of improved resolution at a perceived (in a stereoscopic view) center of the field of view of the user of foveated displays 601, 602. In the illustrated example, center points 611, 612 are the center points of each of regions 401-403. In other examples, one or more of regions 401-403 may have a different center point with respect to other(s) of regions 401-403. In an embodiment, center point 611 is the center point of region 401 of foveated display 601 but not of regions 402, 403 of foveated display 601. Similarly, in an embodiment, center point 612 is the center point of region 401 of foveated display 602 but not of regions 402, 403 of foveated display 602.

In an embodiment, foveated displays 601, 602 may each include a gradient reduction in display element densities from a central region of region 401 toward edges of regions 402, 403, 404 as discussed with respect to FIG. 5. For example, the gradient reduction may reduce from a maximum display element density at center points 611, 612 and may decrease with concentric ellipses of increasing sizes toward edges of foveated displays 601, 602. Such a gradient reduction may be linear or non-linear and may have the same or different gradients in the x- and z-directions. In an embodiment, the decrease is more rapid in the x-direction than in the z-direction. In an embodiment, the decrease in each direction is proportional to the edge length of foveated displays 601, 602 (e.g., the decrease may be proportional to the length of the horizontal edges of foveated displays 601, 602 in the x-direction and be proportional to the length of the vertical edges of foveated displays 601, 602 in the z-direction).

In the illustrated example, foveated displays 601, 602 each include four regions of different display element densities. Such display element densities may be any densities discussed. In other examples, one or both of foveated displays 601, 602 include two, three, five, or more regions of different display element densities including any such examples provided herein.

FIG. 7 is an illustrative diagram of an example virtual reality system 700 including dual foveated displays, arranged in accordance with at least some implementations of the present disclosure. As shown in FIG. 7, system 700 may include foveated displays 601, 602, a circuit board 704, left and right optics 702, 703, and an integrated system 706 disposed within a housing 705. For example, integrated system 706 may implement a microprocessor as discussed herein and foveated displays 601, 602 may be part of a foveated display device coupled to the microprocessor. Although illustrated with respect to a two display system including foveated displays 601, 602 for the sake of clarity of presentation, virtual reality system 700 may include any suitable foveated display discussed herein. For example, a single display virtual reality system may include a single foveated display in place of foveated displays 601, 602 such that the single foveated display may include foveated display 100, 200, 400, 500, or any other suitable single foveated display discussed herein. For example, the foveated display implemented by virtual reality system 700 may include emissive or passive display elements at different densities within regions of the foveated display(s) as discussed herein. As shown, in an embodiment, foveated displays 601, 602 are mounted within housing 705 such that edge 615 of foveated display 601 is adjacent to edge 616 of foveated display 602 as discussed with respect to FIG. 6.

In an embodiment, foveated displays 601, 602 may provide an image to a user 701 via optics 702, 703 (e.g., a left optic 702 and a right optic 703) such that user 701 experiences a stereoscopic virtual image. Similarly, in a single foveated display implementation, the single foveated display may provide an image to user 701 via optics 702, 703 (e.g., a left optic 702 and a right optic 703) such that user 701 experiences a stereoscopic virtual image. Single foveated display implementations may provide the advantage of ease of implementation as well as for the use of the foveated display outside of virtual reality system 700. For example, the single foveated display, circuit board 704, and integrated system 706 may be provided via a mobile device that may be removably coupled to or inserted within housing 705 having optics 702, 703.

Optics 702, 703 may include any suitable optics for presenting a virtual image to user 701 such as lenses or the like. Circuit board 704 may be include any suitable circuitry for transmitting virtual image data to foveated displays 601, 602 and/or for powering a backlight (if applicable). In some examples, circuit board 704 may not be included and such functionality may be provided by flexible substrates, or other components. Housing 705 may include any suitable mechanical support for optics 702, 703, foveated displays 601, 602, circuit board 704, and/or integrated system 706 such as a chassis or the like. In some embodiments, housing 705 is implemented as a virtual reality headset that may be worn by user 701.

As discussed, virtual reality system 700 may provide virtual imagery to user 701. For example, integrated system 706 may generate virtual image data for display to user 701. Integrated system 706 may generate virtual image data using any suitable technique or techniques. Foveated displays 601, 602 may receive the virtual image data via circuit board 704 and may display images corresponding to the virtual image data. User 701 may view the images through optics 702, 703 (e.g., such that user 701, optics 702, 703, and foveated displays 601, 602 are optically coupled) such that the user attains a virtual reality experience.

FIG. 7 illustrates a virtual reality system implementing a foveated display or displays in the context of a virtual reality headset environment. However, the foveated display or displays may be implemented in any suitable augmented reality system or the like. Furthermore, the foveated display or displays may be implemented in augmented reality systems.

FIG. 8A is an illustrative diagram of an example augmented reality system 800 including a foveated display, arranged in accordance with at least some implementations of the present disclosure. As shown in FIG. 8A, system 800 may include a foveated display 801, a waveguide 803, a holographic beam splitter 804 and a holographic beam splitter 805 disposed on opposite ends of waveguide 803, and an integrated system 806. Foveated display 801 may include any suitable foveated display discussed herein. For example, foveated display 801 may include emissive or passive display elements at different densities within regions of foveated display 801 as discussed herein. In an embodiment, foveated display 801 may provide a projected image 802 (e.g., a foveated projected image) to waveguide 803 and holographic beam splitter 805 disposed on waveguide 803. For example, foveated display 801 and waveguide 803 may be optically coupled such that projected image 802 may be provided to waveguide 803. Foveated display 801 and waveguide 803 may be optically coupled using any suitable configuration such as foveated display 801 and waveguide 803 being provided adjacent to one another, foveated display 801 and waveguide 803 being coupled by an optical waveguide (not shown), or the like.

As shown, holographic beam splitter 804 and holographic beam splitter 805 are provided on opposite ends of waveguide 803 and on a shared side 807 of waveguide 803 opposite a side 808 corresponding to the optical coupling to foveated display 801. For example, integrated system 806 may generate virtual image data for display to user 601. Integrated system 806 may generate virtual image data using any suitable technique or techniques. Foveated display 801 may receive the virtual image data and may provide projected image 802. Projected image 802 may enter the end of waveguide 803 having holographic beam splitter 804 via side 808 of waveguide 803 and projected image 802 may be transmitted by waveguide 803 (e.g., via internal reflection of projected image 802 inside the thickness of the glass plate of waveguide) to holographic beam splitter 805 such that virtual image 813 is provided within a field of view 809 of user 601.

As discussed, FIG. 8A illustrates an augmented reality system implementing a foveated display in the context of a holographic beam splitter embodiment. However, the foveated display may be implemented in any suitable augmented reality system or the like.

FIG. 8B is an illustrative diagram of another example augmented reality system 810 including a foveated display, arranged in accordance with at least some implementations of the present disclosure. As shown in FIG. 8B, system 810 may include foveated display 801, a visual layer 811 having a prism 812, and integrated system 806. For example, foveated display 801 may include any suitable foveated display discussed herein. In an embodiment, foveated display 801 may provide projected image 802 (e.g., a foveated projected image) to visual layer 811 and prism 812 such that prism 812 projects a corresponding image to user 601 within field of view 809.

Visual layer 811 and prism 812 may include any suitable materials in any suitable configuration. For example, visual layer 811 and prism 812 may be provided optically coupled to foveated display 801 to provide a virtual image to user 601. For example, integrated system 806 may generate virtual image data for display to user 601. Foveated display 801 may receive the virtual image data and may provide projected image 802. Projected image 802 may enter visual layer 811 and prism 812 may project the image to user 601. Furthermore, user 601 may view field of view 809 through visual layer 811 and prism 812 such that the projected image provides an augmented reality with respect to field of view 809.

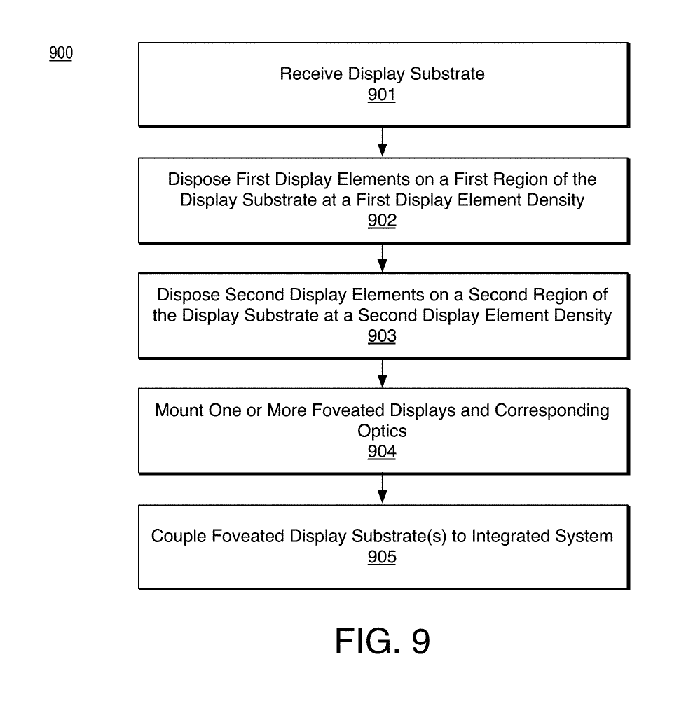

FIG. 9 is a flow diagram illustrating an example process 900 for fabricating a foveated display device, arranged in accordance with at least some implementations of the present disclosure. For example, process 900 may be implemented to fabricate any foveated display device or system discussed herein. In the illustrated implementation, process 900 may include one or more operations as illustrated by operations 901-904. However, embodiments herein may include additional operations, certain operations being omitted, or operations being performed out of the order provided.

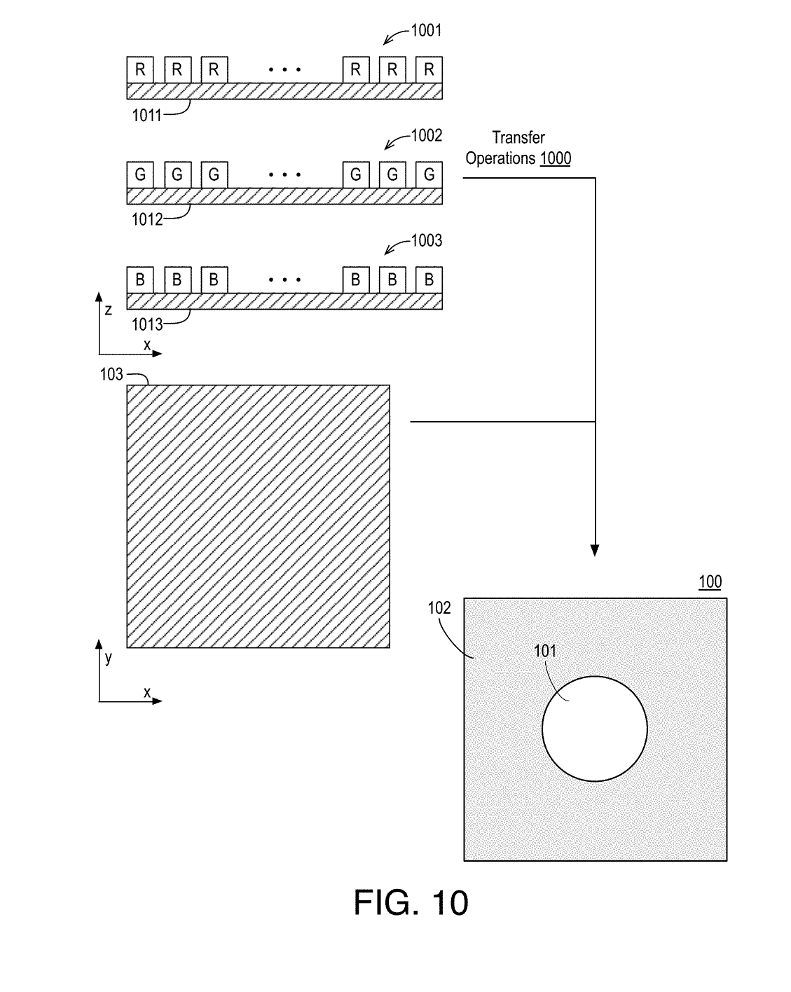

Process 900 may begin at operation 901, where a display substrate may be received. The display substrate may be any suitable display substrate for mounting or fabricating display elements thereto as discussed herein. Process 900 may continue at operation 902, where first display elements may be disposed on a first region of the display substrate at a first display element density and at operation 903, where second display elements may be disposed on a second region of the display substrate at a second display element density such that the first display element density is greater than the second display element density. The first and second display elements may be disposed on their respective regions of the display substrate using any suitable technique or techniques. In some embodiments, operations 902 and 903 may be performed in series and, in other embodiments, operations 902 and 903 may be performed in parallel. As discussed, operations 902 and 903 may be performed using any suitable technique or techniques. In some embodiments, operations 902 and 903 may include disposing the first and second display elements on their respective regions of the display substrate using pick and place operations as discussed with respect to FIG. 10. In some embodiments, operations 902 and 903 may include fabricating the first and second display elements on their respective regions of the display substrate using selective fabrication techniques such as selective lithography and fabrication techniques. For example, the display element density distribution may be defined using photolithography techniques. Although illustrated with respect to operations 902 and 903 to dispose first and second regions of display elements at first and second display element densities, process 900 may include further processing to dispose any number of regions of display elements at a corresponding number of display element densities such as three regions of three display element densities, four regions of four display element densities, five regions of five display element densities, and so on as discussed herein or at display element densities having a gradient as discussed herein.

Process 900 may continue at operation 904, where one or more foveated displays on one or more display substrates generated by operations 901-903 may be mounted along with corresponding optics into a system such as a virtual reality system or an augmented reality system. The one or more foveated displays and corresponding optics may be mounted into the virtual reality or augmented reality system using any suitable technique or techniques. In an embodiment, a foveated display or displays generated by operations 901-903 and optics 702, 703 may be mounted within housing 705 of virtual reality system 700 as discussed with respect to FIG. 7. In an embodiment, a foveated display or displays generated by operations 901-903 and waveguide 803 having holographic beam splitters 804, 805 disposed thereon may be mounted within a housing or implemented via augmented reality glasses or the like of augmented reality system 800 as discussed with respect to FIG. 8A. In an embodiment, a foveated display or displays generated by operations 901-903 and visual layer 811 having prism 812 may be mounted within a housing or implemented via augmented reality glasses or the like of augmented reality system 810 as discussed with respect to FIG. 8B.

Process 900 may continue at operation 905, where the one or more foveated displays and, optionally, the optics mounted at operation 904 may be coupled to an integrated system. The one or more foveated displays may be coupled to the integrated system using any suitable technique or techniques. For example, the one or more foveated displays and components of the integrated system may coupled via circuit board or the like. In various embodiments, the one or more foveated displays may be coupled to an integrated system of a virtual reality system as discussed with respect to FIG. 7, an integrated system of an augmented reality system as discussed with respect to FIGS. 8A and 8B, or an integrated system of a system having any suitable form factor discussed herein.

Process 900 may be utilized to generate any foveated display or displays and/or any virtual reality or augmented reality systems as discussed herein such as foveated displays 100, 200, 400, 500, 601, 602 and/or virtual reality system 700, augmented reality system 800, or augmented reality system 810.

FIG. 10 illustrates example pick and place operations for the fabrication of a foveated display device, arranged in accordance with at least some implementations of the present disclosure. For example, FIG. 10 may illustrate example micro-transfer techniques. In such contexts, the fabrication of a foveated display device may be less costly than that of a full resolution display device (e.g., a display having all regions at the display element density of the highest display element density of the foveated display) due to the reduced number of pick and place operations required. In an embodiment, FIG. 10 may be applied to LED or micro-LED implementations. For example, red, green, and blue LEDs or micro-LEDs may be made on appropriate wafers and transferred to a display substrate to fabricate a foveated display.

As shown in FIG. 10, red emitters 1001 may be formed on a substrate (or carrier) 1011, green emitters 1002 may be formed on a separate substrate (or carrier) 1012, and blue emitters 1003 may be formed on a separate substrate (or carrier) 1013 using known techniques. For example, substrates 1011, 1012, 1013 may be separate monolithic silicon or sapphire wafers or the like such that red emitters 1001, green emitters 1002, and blue emitters 1003 are formed in separate processing operations. Red emitters 1001, green emitters 1002, and blue emitters 1003 may be any suitable display elements such as LEDs, micro-LEDs, Also as shown in FIG. 10, red emitters 1001, green emitters 1002, and blue emitters 1003 may be transferred (e.g., picked and placed) from substrates 1011, 1012, 1013, respectively, onto substrate 103 to generate foveated display 100 via transfer operations 1000. For example, red emitters 1001, green emitters 1002, and blue emitters 1003 may be transferred from substrates 1011, 1012, 1013, in turn, to generate foveated display 100. For example, such transfer processes may be executed three times for the three colors of each display element of foveated display 100. In some embodiments, each display element or pixel location of foveated display 100 includes two of each red emitters 1001, green emitters 1002, and blue emitters 1003 for the purposes of redundancy. Although illustrated with respect to foveated display 100, any foveated display discussed herein may be fabricated using such pick and place techniques. As discussed, due to the lower display element density in region 102, throughput may be increased and production costs may be decreased with respect to a full resolution display.

The devices, systems, and fabrication techniques discussed herein provide foveated display device(s) that have regions of differing display element densities. Such foveated display devices may be less costly to manufacture and require less energy during operation with respect full resolution displays.

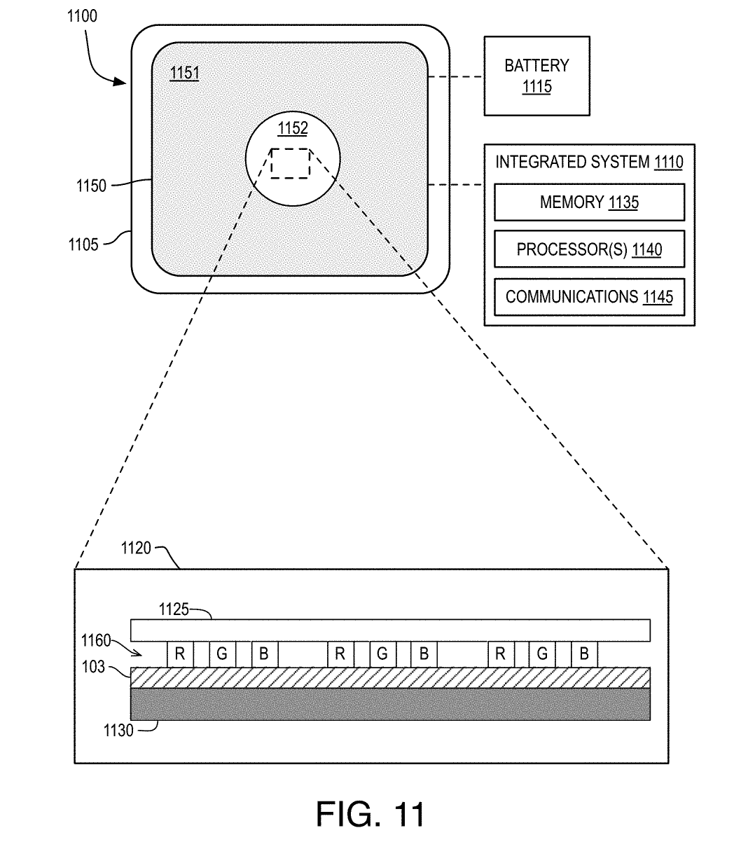

FIG. 11 illustrates a system 1100 in which a mobile computing platform 1105 employs a foveated display, arranged in accordance with at least some implementations of the present disclosure. Mobile computing platform 1105 may be any portable device configured for each of electronic data display, electronic data processing, wireless electronic data transmission, or the like. For example, although illustrated as a tablet, mobile computing platform 1105 may be any of a tablet, a smartphone, a phablet, a laptop computer, a watch, an augmented reality device, a virtual reality device, a headset etc., and may include a foveated display 1150, which may be any foveated display discussed herein.

Also as illustrated in expanded view 1120, foveated display 1150 may include a glass front plate 1125, a back plane or plate 1130, and display elements 1160 disposed on substrate 103. Display elements 1160 may be any display elements discussed herein at any suitable display element density. As shown, foveated display 1150 may include regions 1151, 1152 such that region 1152 has a higher display element density than region 1151. However, foveated display 1150 may have any number of regions having any suitable display element densities of any shapes, etc. as discussed herein.

As shown, glass front plate 1125 may be disposed adjacent to and/or over display elements 1160 and glass front plate 1125 may provide protection for such components and/or other structures of foveated display 1150 as well as a monolithic display structure for a viewer of foveated display 1150. Back plane 1130 may similarly provide a monolithic structure for implementing and/or display elements 1160 and/or substrate 103 and/or other components of foveated display 1150. In an embodiment, a driver circuit is implemented via backplane 1130. Furthermore, glass front plate 1125 and/or back plane 1130 may provide components of and/or be provided within a housing of system 1100. As will be appreciated, glass front plate 1125 and backplane 1130 may also be provided adjacent to display elements (at a lower display element density) of region 1151 of foveated display 1150.

Although illustrated with respect to a single foveated display 1150, any suitable foveated display or number of foveated displays, such as foveated displays 200, 300, 400, 500, 601, 602, or the like, may be implemented in system 1100. Furthermore, foveated display 1150 may provide touch capability via a capacitive, inductive, resistive, or optical touchscreen. Also as shown, mobile computing platform 1105 includes a chip-level or package-level integrated system 1110 and a battery 1115. Although illustrated with respect to mobile computing platform 1105, the foveated displays discussed herein may also be employed via a display of a desktop computer, television, or the like.

Integrated system 1110 may be implemented as discrete components (e.g., integrated circuits) or as a system on a chip and may include may include memory circuitry 1135 (e.g., random access memory, storage, etc.), processor circuitry 1140 (e.g., a microprocessor, a multi-core microprocessor, graphics processor, etc.), and communications circuitry 1145 (e.g., a wireless transceiver, a radio frequency integrated circuit, a wideband RF transmitter and/or receiver, etc.). The components of integrated system 1110 may be communicatively coupled to one another for the transfer of data within integrated system 1110. Functionally, memory circuitry 1135 may provide memory and storage for integrated system 1110 including image and/or video data for display by foveated display 1150, processor circuitry 1140 may provide high level control for mobile computing platform 1105 as well as operations corresponding to generating image and/or video data for display by foveated display 1150, and communications circuitry 1145 may transmit and/or receive data including image and/or video data for display by foveated display 1150. For example, communications circuitry 1145 may be coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond.

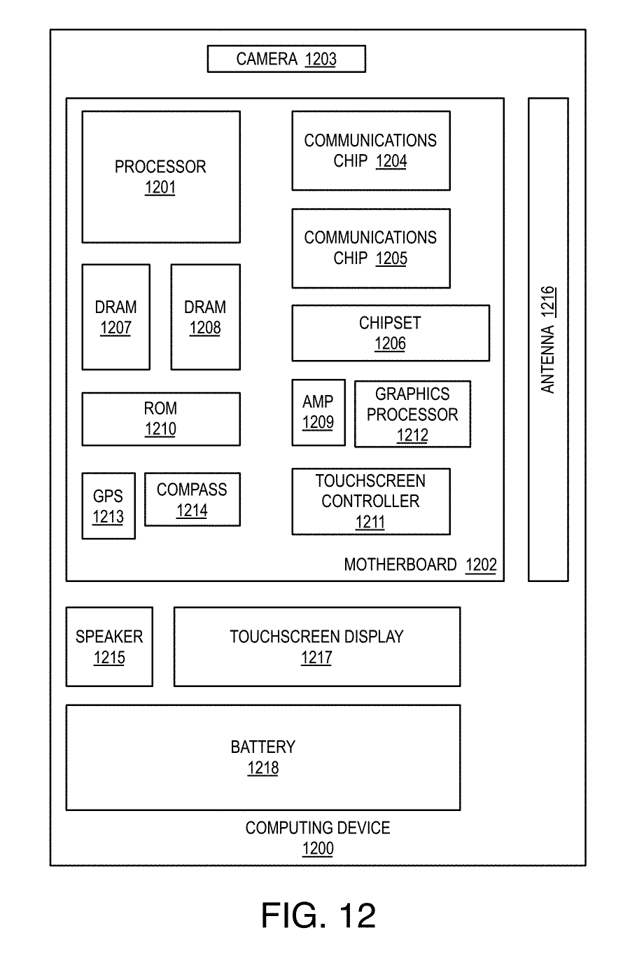

FIG. 12 is a functional block diagram of a computing device 1200, arranged in accordance with at least some implementations of the present disclosure. Computing device 1200 or portions thereof may be implemented via mobile computing platform 1105, for example, and further includes a motherboard 1202 hosting a number of components, such as, but not limited to, a processor 1201 (e.g., an applications processor, a microprocessor, etc.) and one or more communications chips 1204, 1205. Processor 1201 may be physically and/or electrically coupled to motherboard 1202. In some examples, processor 1201 includes an integrated circuit die packaged within the processor 1201. In general, the term “processor” may refer to any device or portion of a device that processes electronic data from registers and/or memory to transform that electronic data into other electronic data that may be stored in registers and/or memory.

In various examples, one or more communication chips 1204, 1205 may also be physically and/or electrically coupled to the motherboard 1202. In further implementations, communication chips 1204 may be part of processor 1201. Depending on its applications, computing device 1200 may include other components that may or may not be physically and electrically coupled to motherboard 1202. These other components may include, but are not limited to, volatile memory (e.g., DRAM) 1207, 1208, non-volatile memory (e.g., ROM) 1210, a graphics processor 1212, flash memory, global positioning system (GPS) device 1213, compass 1214, a chipset 1206, an antenna 1216, a power amplifier 1209, a touchscreen controller 1211, a touchscreen display 1217, a speaker 1215, a camera 1203, and a battery 1218, as illustrated, and other components such as a digital signal processor, a crypto processor, an audio codec, a video codec, an accelerometer, a gyroscope, and a mass storage device (such as hard disk drive, solid state drive (SSD), compact disk (CD), digital versatile disk (DVD), and so forth), or the like. For example, touchscreen display 1217 may implement any emissive display device structure(s) discussed herein.

Communication chips 1204, 1205 may enable wireless communications for the transfer of data to and from the computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1204, 1205 may implement any of a number of wireless standards or protocols, including but not limited to those described elsewhere herein. As discussed, computing device 1200 may include a plurality of communication chips 1204, 1205. For example, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others. For example, one or both of communication chips 1204, 1205 may provide a wireless transceiver for computing device 1200. As discussed, touchscreen display 1217 of computing device 1200 may include or utilize one or more emissive display device structures discussed herein.

As used in any implementation described herein, the term “module” refers to any combination of software, firmware and/or hardware configured to provide the functionality described herein. The software may be embodied as a software package, code and/or instruction set or instructions, and “hardware”, as used in any implementation described herein, may include, for example, singly or in any combination, hardwired circuitry, programmable circuitry, state machine circuitry, and/or firmware that stores instructions executed by programmable circuitry. The modules may, collectively or individually, be embodied as circuitry that forms part of a larger system, for example, an integrated circuit (IC), system on-chip (SoC), and so forth.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

The following examples pertain to further embodiments.

In one or more first examples, a foveated display device comprises a plurality of first display elements on a first region of a display substrate, wherein the first display elements have a first display element density and a plurality of second display elements on a second region of the display substrate, wherein the second display elements have a second display element density that is less than the first display element density.

In one or more second examples, for any of the first examples, the first region and the second region are continuous regions and the second region surrounds the first region.

In one or more third examples, for any of the first or second examples, the first region and the second region are adjacent regions and the foveated display device comprises a gradient reduction in display element densities from a central region of the first region to an edge of the second region.

In one or more fourth examples, for any of the first through third examples, the foveated display device further comprises a plurality of third display elements on a third region of the display substrate, wherein the third display elements have a third display element density that is less than the second display element density.

In one or more fifth examples, for any of the first through fourth examples, the foveated display device further comprises a plurality of third display elements on a third region of the display substrate such that the third display elements have a third display element density that is less than the second display element density such that each of the third display elements are farther from a center point of the first region than each of the second display elements.

In one or more sixth examples, for any of the first through fifth examples, the foveated display device further comprises a plurality of third display elements on a third region of the display substrate such that the third display elements have a third display element density that is less than the second display element density and a plurality of fourth display elements on a fourth region of the display substrate such that the fourth display elements have a fourth display element density that is less than the third display element density, the second display element density is not more than three-quarters of the first display element density, the third display element density is not more than one-half of the first display element density, and the fourth display element density is not more than one-quarter of the first display element density.

In one or more seventh examples, for any of the first through sixth examples, the display substrate is a monolithic display substrate, and wherein each of the first and second display elements comprise a red inorganic light emitting diode, a green organic light emitting diode, and a blue organic light emitting diode.

In one or more eighth examples, for any of the first through seventh examples, the first region has an elliptical shape having a major axis to minor axis ratio that is not more than two percent different than an aspect ratio of the display substrate.

In one or more ninth examples, for any of the first through eighth examples, a center point of the first region is aligned with a center point of the display substrate.

In one or more tenth examples, for any of the first through ninth examples, the foveated display device further comprises a plurality of third display elements on a third region of a second display substrate such that the third display elements have a third display element density and a plurality of fourth display elements on a fourth region of the second display substrate such that the fourth display elements have a fourth display element density that is less than the third display element density.

In one or more eleventh examples, for any of the first through tenth examples, the display substrate and the second display substrate are mounted in a housing with a first edge of the display substrate adjacent to a second edge of the second display substrate and such that a center point of the first region is between a center point of the display substrate and the first edge of the display substrate.

In one or more twelfth examples, for any of the first through eleventh examples, a center point of the first region is between a center point of the first display substrate and the first edge and a center point of the second region is between a center point of the second display substrate and the second edge.

In one or more thirteenth examples, for any of the first through twelfth examples, the first display element density and the third display element density are not more than one percent different than one another and/or the second display element density and the fourth display element density are not more than one percent different than one another.

In one or more fourteenth examples, for any of the first through thirteenth examples, the first region and the second region both have an elliptical shape.

In one or more fifteenth examples, for any of the first through fourteenth examples, each of the first and second display elements comprises a red light emitting diode, a green light emitting diode, and a blue light emitting diode.

In one or more sixteenth examples, for any of the first through fifteenth examples, a system such as a virtual reality display system comprises a microprocessor, a foveated display device coupled to the microprocessor, the foveated display device comprising any foveated display device of the first through fifteenth examples, and one or more optics adjacent to the foveated display device.

In one or more seventeenth examples, a method for fabricating a foveated display device comprises receiving a display substrate, disposing a plurality of first display elements on a first region of the display substrate such that the first display elements have a first display element density, and disposing a plurality of second display elements on a second region of the display substrate such that the second display elements have a second display element density that is less than the first display element density.

In one or more eighteenth examples, for any of the seventeenth examples, each of the first and second display elements comprises a red emitter, a green emitter, and a blue emitter and disposing the plurality of first display elements and the plurality of second display elements comprises a pick and place operation of the red emitters, green emitters, and blue emitters from one or more carrier substrates.

In one or more nineteenth examples, for any of the seventeenth or eighteenth examples, each of the first display elements comprises a first red light emitting diode, a first green light emitting diode, and a first blue light emitting diode having a first distance therebetween and each of the second display elements comprises a second red light emitting diode, a second green light emitting diode, and a second blue light emitting diode having a second distance therebetween such that the first distance is less than the second distance.

In one or more twentieth examples, for any of the seventeenth through nineteenth examples, the method further comprises disposing a plurality of third display elements on a third region of the display substrate such that the third display elements have a third display element density that is less than the second display element density and disposing a plurality of fourth display elements on a fourth region of the display substrate such that the fourth display elements have a fourth display element density that is less than the third display element density, the second display element density is not more than three-quarters of the first display element density, the third display element density is not more than one-half of the first display element density, and the fourth display element density is not more than one-quarter of the first display element density.

It will be recognized that the embodiments is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

1. A foveated display device comprising:
a plurality of first display elements on a first region of a display substrate, wherein the first display elements have a first display element density, wherein each of the first display elements comprises a plurality of first sub-display elements each of a first size, and wherein the plurality of first sub-display elements are spaced apart from each other at a first pitch; and
a plurality of second display elements on a second region of the display substrate, wherein the second display elements have a second display element density that is less than the first display element density, wherein each of the second display elements comprises a plurality of second sub-display elements each of the first size, and wherein the plurality of second sub-display elements are spaced apart from each other at a second pitch greater than the first pitch.

2. The foveated display device of claim 1, wherein the first region and the second region are continuous regions and the second region surrounds the first region.

3. The foveated display device of claim 1, wherein the first region and the second region are adjacent regions and the foveated display device comprises a gradient reduction in display element densities from a central region of the first region to an edge of the second region.

4. The foveated display device of claim 3, wherein the gradient reduction in display element densities comprises a first density decrease in the central region and a second density decrease in the edge region, and wherein the first density decrease is less than the second density decrease.

5. The foveated display device of claim 3, wherein the gradient reduction is more rapid in an x-direction aligned with a bottom of the foveated display device than in a z-direction aligned with a side of the foveated display device.

6. The foveated display device of claim 1, further comprising:
a plurality of third display elements on a third region of the display substrate; and
a plurality of fourth display elements on a fourth region of the display substrate, wherein the fourth display elements have a fourth display element density that is less than the third display element density, wherein the second display element density is not more than three-quarters of the first display element density, the third display element density is not more than one-half of the first display element density, and the fourth display element density is not more than one-quarter of the first display element density.

7. The foveated display device of claim 1, wherein the first region comprises a cross shape.

8. The foveated display device of claim 1, wherein the first region has an elliptical shape having a major axis to minor axis ratio that is not more than two percent different than an aspect ratio of the display substrate.

9. The foveated display device of claim 1, wherein a center point of the first region is aligned with a center point of the display substrate.

10. The foveated display device of claim 1, further comprising:
a plurality of third display elements on a third region of a second display substrate, wherein the third display elements have a third display element density; and
a plurality of fourth display elements on a fourth region of the second display substrate, wherein the fourth display elements have a fourth display element density that is less than the third display element density.

11. The foveated display device of claim 10, wherein the display substrate and the second display substrate are mounted in a housing with a first edge of the display substrate adjacent to a second edge of the second display substrate and wherein a center point of the first region is between a center point of the display substrate and the first edge of the display substrate.

12. The foveated display device of claim 1, wherein the first sub-display elements comprise at least one of a micro light emitting diode, an organic light emitting diode, or a liquid crystal display element.

13. The foveated display device of claim 1, wherein the plurality of first sub-display elements consists of a first red emitter, a first green emitter, and a first blue emitter having the first size and spaced apart from each other at the first pitch and the plurality of second sub-display elements consists of a second red emitter, a second green emitter, and a second blue emitter having the first size and spaced apart from each other at the second pitch.

14. A virtual reality display system comprising:
a microprocessor;
a foveated display device coupled to the microprocessor, the foveated display device comprising:
a first display substrate and a second display substrate mounted in a housing with a first edge of the display substrate adjacent to a second edge of the second display substrate;
a plurality of first display elements on a first region of the first display substrate, wherein the first display elements have a first display element density, wherein each of the first display elements comprises a plurality of first sub-display elements each of a first size, and wherein the plurality of first sub-display elements are spaced apart from each other at a first pitch;
a plurality of second display elements on a second region of the display substrate, wherein the second display elements have a second display element density that is less than the first display element density, wherein each of the second display elements comprises a plurality of second sub-display elements each of the first size, and wherein the plurality of second sub-display elements are spaced apart from each other at a second pitch greater than the first pitch;
a plurality of third display elements on a third region of the second display substrate, wherein the third display elements have a third display element density; and
a plurality of fourth display elements on a fourth region of the second display substrate, wherein the fourth display elements have a fourth display element density that is less than the third display element density; and
one or more optics adjacent to the foveated display device.

15. The virtual reality display system of claim 14, wherein a center point of the first region is between a center point of the first display substrate and the first edge and a center point of the second region is between a center point of the second display substrate and the second edge.

16. The virtual reality display system of claim 14, wherein the first region and the second region are adjacent regions and the foveated display device comprises a gradient reduction in display element densities from a central region of the first region to an edge of the second region, wherein the gradient reduction in display element densities comprises a first density decrease in the central region and a second density decrease in the edge region, and wherein the first density decrease is less than the second density decrease.

17. The virtual reality display system of claim 14, wherein the first region and the second region are adjacent regions and the foveated display device comprises a gradient reduction in display element densities from a central region of the first region to an edge of the second region, wherein the gradient reduction is more rapid in an x-direction aligned with a bottom of the foveated display device than in a z-direction aligned with a side of the foveated display device.

18. The virtual reality display system of claim 14, wherein the plurality of first sub-display elements consists of a first red emitter, a first green emitter, and a first blue emitter having the first size and spaced apart from each other at the first pitch and the plurality of second sub-display elements consists of a second red emitter, a second green emitter, and a second blue emitter having the first size and spaced apart from each other at the second pitch.

19. A method for fabricating a foveated display device comprising:
receiving a display substrate;
disposing a plurality of first display elements on a first region of the display substrate, wherein the first display elements have a first display element density, wherein each of the first display elements comprises a plurality of first sub-display elements each of a first size, and wherein the plurality of first sub-display elements are spaced apart from each other at a first pitch; and
disposing a plurality of second display elements on a second region of the display substrate, wherein the second display elements have a second display element density that is less than the first display element density, wherein each of the second display elements comprises a plurality of second sub-display elements each of the first size, and wherein the plurality of second sub-display elements are spaced apart from each other at a second pitch greater than the first pitch.

20. The method of claim 19, wherein each of the first and second display elements comprises a red emitter, a green emitter, and a blue emitter and wherein disposing the plurality of first display elements and the plurality of second display elements comprises a pick and place operation of the red emitters, green emitters, and blue emitters from one or more carrier substrates.

21. The method of claim 19, wherein the first region and the second region are adjacent regions and the foveated display device comprises a gradient reduction in display element densities from a central region of the first region to an edge of the second region, wherein the gradient reduction in display element densities comprises a first density decrease in the central region and a second density decrease in the edge region, and wherein the first density decrease is less than the second density decrease.

22. The method of claim 19, further comprising:
disposing a plurality of third display elements on a third region of the display substrate, wherein the third display elements have a third display element density that is less than the second display element density; and
disposing a plurality of fourth display elements on a fourth region of the display substrate, wherein the fourth display elements have a fourth display element density that is less than the third display element density, wherein the second display element density is not more than three-quarters of the first display element density, the third display element density is not more than one-half of the first display element density, and the fourth display element density is not more than one-quarter of the first display element density.
